(19) United States
(12) Patent Application Publication
(10) Pub. No.: US 2012/0118345 A1
(43) Pub. Date: May 17, 2012

(54) Thermal integration of thermoelectronic device

(75) Inventors: Michael F. Stoia, Rancho Santa Margarita, CA (US); David W. Kwok, La Mirada, CA (US); James P. Huang, Huntington Beach, CA (US)

(73) Assignee: THE BOEING COMPANY

(21) Appl. No.: 12/927,466

(22) Filed: Nov. 15, 2010

(51) Int. Cl. H01L 35/30

(52) U.S. Cl. 136/205

(57) ABSTRACT

Disclosed is an improved thermoelectric component, a method for thermal integration of the improved thermoelectric component in an environment having thermally distinct zones, and a thermoelectric generation system. In general, the thermoelectric component includes a thermoelectric device having opposing surfaces for arrangement in comparatively hot and cold environments, and an extended surface mounted in close proximity to at least one of the opposing surfaces, the extended surface being a layer of porous material having at least a portion immersed in at least one of the hot or cold environments.

### FIELD OF THE DISCLOSURE

The present disclosure relates generally to thermoelectric devices, and more particularly to an improved thermoelectric device and arrangements of thermoelectric devices for generating electricity through convective heat transfer from fluid streams.

Combustion turbine/systems are widely used for power generation. Combustion turbines, also known as gas turbine engines, are known to utilize fuel sources such as natural gas, petroleum, or finely divided, particulate material. Gas-fueled combustion turbine/generator systems have become a particularly attractive way of generating electrical energy because they may be more rapidly brought to an operational state than other types of generating systems.

Gas turbine engines typically include an air intake side and a heat exhaust side. Air is forced into the combustion chamber by a compressor, which is typically formed from a plurality of fan blades within a wheel. Injectors introduce fuel into the combustion chamber and the fuel is ignited. The turbine engine is capable of operating with a wide variety of fuels, including natural gas, gasoline, kerosene, and basically anything that burns. The hot combustion gases that form as a result of the combustion spin the turbine(s), which are also typically formed of fan blade-type structures within a wheel. The turbine(s) are connected to the main shaft, which is connected to the electrical generator. As the turbine(s) spins, the main shaft spins and operates the electrical generator to produce energy. The heat exhaust is expelled from the turbine engine generator into the atmosphere at the heat exhaust end of the turbine engine.

A thermoelectric device (TD) is a device that can generate electricity when a temperature differential is applied across the device. A thermoelectric device (TD) is typically square or rectangular with the upper and lower end-caps having the same dimension and typically power generated by thermoelectric devices is transmitted via a set of power wires. Thermoelectric device (TD) are typically thin (e.g., in the order of a couple of millimeters thick), small (e.g., a couple of square centimeters), flat, and brittle. Accordingly, thermoelectric devices can be difficult to handle individually, especially for applications in vehicles, such as automobiles, aircraft and the like, where the thermoelectric devices can be subject to harsh environmental conditions, such as vibration, constant temperature variations and other harsh conditions. Because of their size and the fact that each thermoelectric device generates only a small amount of power, many thermoelectric devices are bundled together in order to generate a useful amount of power. Further, thermoelectric devices generally provide greater energy conversion efficiency at high temperature differentials. This can cause relatively large thermal expansion in materials. Because of thermal gradients and different thermal coefficients of expansion associated with different materials, thermally induced stresses may result.

As noted above, efficiency of thermoelectric devices generally increases with greater temperature differentials, i.e., delta temperature between two opposite sides, typically called the heat source (hot side) and heat sink (cold side) of the thermoelectric device. Also, energy conversion efficiency is maximized for any installation that channels heat flow through the thermoelectric devices only without any thermal energy leaks through the surrounding structural material or gaps. Thus, to simplify handling and achieve high performance in converting heat to electricity, multiple thermoelectric devices can be encased into a module or assembly prior to final installation.

FIG. 1 is an example of one known thermoelectric generator assembly 100 or module in which a plurality of thermoelectric devices 102 are disposed between two structural plates 104 and 106. Each of the structural plates 104 and 106 may be made of a thermally conductive material to spread the heat on both hot and cold sides of the thermoelectric module 100. One of the plates, such as upper structural plate 104, may define a cold spreader plate and may be thermally coupled to a cold side 108 of each of the thermoelectric devices 102. The other plate, such as the lower structural plate 106, may define a hot spreader plate and be coupled to a hot side 110 of each of the thermoelectric devices 102. Each of the plates 104 and 106 may be respectively thermally coupled to the cold side 108 and hot side 110 of each of the thermoelectric devices 102. Vacuum gaps 116 or insulation material may be used to separate each thermoelectric device 102 in the module 100 to maximize heat flow through thermoelectric devices 102. Additional insulation may be required to prevent heat losses through the sides.

FIG. 2 shows an array 30 of thermoelectric devices 32 sandwiched between metallic face sheets. One side of the array of thermoelectric devices is exposed to a heated or “hot” environment and covering that heated side of the array is a first face sheet 34. The opposing side of the array of thermoelectric devices exposed to a cooler or “cold” environment and a second face sheet 36 covers that “cold” side of the array. The face sheets 34 and 36 act to evenly distribute the heat or cold, respectively, over the side of the array of devices to which it is adjacently arranged.

FIG. 3 schematically illustrates a thermoelectric generator 101 installed in a turbine engine where a higher temperature heat source and a lower temperature heat sink are readily available in close proximity to one another, e.g., separated by a compartment cowling or nozzle. FIG. 3 is taken from the co-pending, commonly-owned, patent application having U.S. Publication Number 2009/0159110 A1, filed Jun. 25, 2009 (the entire disclosure of which is incorporated herein in its entirety). The thermoelectric generator 101 can be installed such that one side thereof, i.e., a hot side 103, receives heat from the turbine engine 105 and such that another side thereof, i.e., a cold side 104, provides heat to flowing air 108. The flow of heat through the thermoelectric generator 101 due to the difference in temperatures .DELTA.T thereacross causes a voltage .DELTA.V to be generated across terminals 112 of the thermoelectric generator 101. Such use of one or more thermoelectric generators 101 to generate electricity can be very efficient, because it does not require mechanical work to be performed by the turbine engine. Rather, it uses waste heat that is produced by the turbine engine whether or not the thermoelectric generators 101 are present.

Thermoelectric generators 101 can be placed on a turbine engine proximate the turbine engine core cowling and proximate the turbine engine nozzle. Both of these locations provide a source of heat and a source of cooling. The source of heat is the hot gases of the turbine engine. The source of cooling is airflow.

For a turbine engine having a typical mechanically driven electric generator, an increase in electrical demand results in increased fuel consumption, increased air pollution, and higher exhaust temperatures. The air pollution typically includes carbon dioxide, nitrogen oxides, and upper-atmosphere water vapor. However, such an increase in electrical demand does not result in increased fuel consumption, higher exhaust temperatures, and increased air pollution when using thermoelectric generators.

Thermoelectric generators do not increase the load on the turbine engine when there is an increase in electrical demand. The thermoelectric generators generate electricity by capturing waste heat in the turbine engine compartment and/or nozzle. Thus, the efficiency of a turbine engine is not substantially reduced by the addition of thermoelectric generators and can be substantially improved by the elimination of mechanically driven electric generators.

Against this background, it has been found to be difficult to establish a large temperature gradient across a thermoelectric device in applications where the heat flow is governed by forced convection derived from fluids, such as gases and liquids. That is, the fluid flow is not normally capable of transferring heat quickly enough to establish a large temperature gradient across a thermoelectric device. Further, it has been found that thermoelectric devices exhibit fragility and mechanical failure when subjected to thermal and mechanical stresses.

In attempts to overcome these shortcomings, heat pipes have been used to passively augment heat transfer and establish a larger temperature gradient across the TEC device. Heat pipes, however, have been found to preclude the use of thermoelectric devices in high temperature installations where there is potential for larger power production. The challenges associated with the use of heat pipes and pumped coolant loops include the addition of extra or excessive weight, availability of coolant in the system, and reliability (i.e. active components with moving parts).

A passive solution to the problem of establishing a large temperature gradient across a thermoelectric device in instances where the heat flux is governed by forced convection with fluids would therefore be highly desirable.

### SUMMARY OF THE DISCLOSURE

In one aspect of the disclosure, an improved thermoelectric component includes a thermoelectric device having opposing surfaces for arrangement in comparatively hot and cold environments, and an extended surface mounted in close proximity to at least one of the opposing surfaces of the thermoelectric device, where the extended surface includes a layer of porous material having at least a portion immersed in at least one of the hot or cold environments. In one variation of the thermoelectric component, both of the opposing surfaces of the thermoelectric device include a layer of porous material proximate thereto, and at least a portion of both of the layers of porous material are disposed in the hot and cold environments, respectively. In another variation, the porous material is thermally conductive and comprises one of a metal, a ceramic, and a graphitized carbon. The ceramic is chosen from the group of boron nitride, silicon nitride, silicon carbide, hafnium carbide, and tantalum carbide. In still another variation, the porous material has a low coefficient of thermal expansion. In yet another variation, the porous material is thermally conductive and the metal is chosen from the group of copper, aluminum, tin, nickel, silver, and gold. The porous material is ductile and will transfer heat quickly from one of the hot or cold environments to increase convective heat transfer to the thermoelectric component. An array of the thermoelectric devices can be sandwiched between opposing face sheets, wherein the extended surface is mounted adjacent to, and in close proximity with, one of the major surfaces of the opposing face sheets.

In another aspect of the disclosure, a method for thermal integration of a thermoelectric device includes the steps of providing an array of thermoelectric devices, placing a first face sheet in close proximity to, and covering, one side of the array of thermoelectric devices, placing a second face sheet in close proximity to, and covering, an opposing side of the array of thermoelectric devices, providing a first layer of porous material in close proximity to the first face sheet to thereby form an improved thermoelectric component, and positioning the first face sheet adjacent to a heated environment. The method further includes the steps of providing a second layer of porous material in close proximity to the second face sheet, and positioning the second face sheet adjacent to a cooled environment.

In still another aspect of the disclosure, a thermoelectric generation system includes an engine, and at least one thermoelectric device disposed proximate the engine, the thermoelectric device including a porous layer on a surface thereof in proximity to the engine. The thermoelectric device is disposed proximate a heat source of the engine and a cooling source of the environment. The thermoelectric device has two opposing surfaces bearing the porous layer, one surface being disposed proximate to the engine and the other surface being disposed proximate to an air flow. In one embodiment, the engine is a turbine engine, and the thermoelectric device is mounted to the engine proximate to the exhaust nozzle. In another embodiment, the engine is a turbine engine, and includes an array of thermoelectric devices sandwiched between opposing face sheets to form a module mounted to the engine proximate to the combustion section. At least one of the face sheets supports the porous material.

In yet another aspect of the disclosure, a method for generating thermoelectric energy includes mounting at least one thermoelectric device proximate an engine, the thermoelectric device including a porous layer on at least one surface thereof in proximity to the engine, wherein the thermoelectric device is disposed proximate a heat source of the engine and a cooling source. The thermoelectric device has two opposing surfaces bearing the porous layer, one surface being disposed proximate to the engine and the other surface being disposed proximate to an air flow. In one variation, the engine comprises a turbine engine, and the thermoelectric device is mounted to the engine proximate to the exhaust nozzle. In another variation, the engine comprises a turbine engine, and further includes an array of thermoelectric devices sandwiched between opposing face sheets to form a module, the module being mounted to the engine proximate to the combustion section.

Further aspects of the apparatus and methods pertaining to the apparatus are disclosed herein. The features as discussed above, as well as other features and advantages of the present disclosure will be appreciated and understood by those skilled in the art from the following detailed description and drawings.

### BRIEF DESCRIPTION OF THE DRAWINGS

FIG. 1 illustrates one embodiment of a known thermoelectric device;

FIG. 2 is a perspective view of an array of thermoelectric devices with hot side and cold side face sheets covering hot and cold sides of the array;

FIG. 3 is a schematic diagram of a conventional thermoelectric device in use;

FIG. 4 is a schematic sectional view of an improved thermoelectric device positioned in proximity to hot and cold sources;

FIG. 5 is a cross-sectional view of a turbine engine showing contemplated placements of the improved thermoelectric device of the present disclosure;

FIG. 6a illustrates one possible configuration of an array of improved thermoelectric devices mounted to a section of a turbine engine, and

FIG. 6b illustrates a second possible configuration of an array of improved thermoelectric devices mounted to a section of a turbine engine.

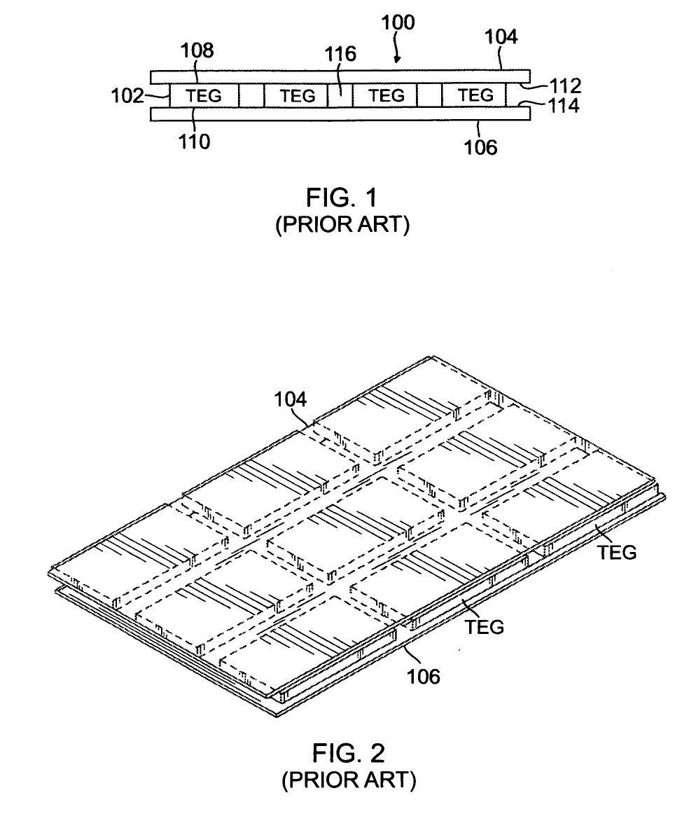

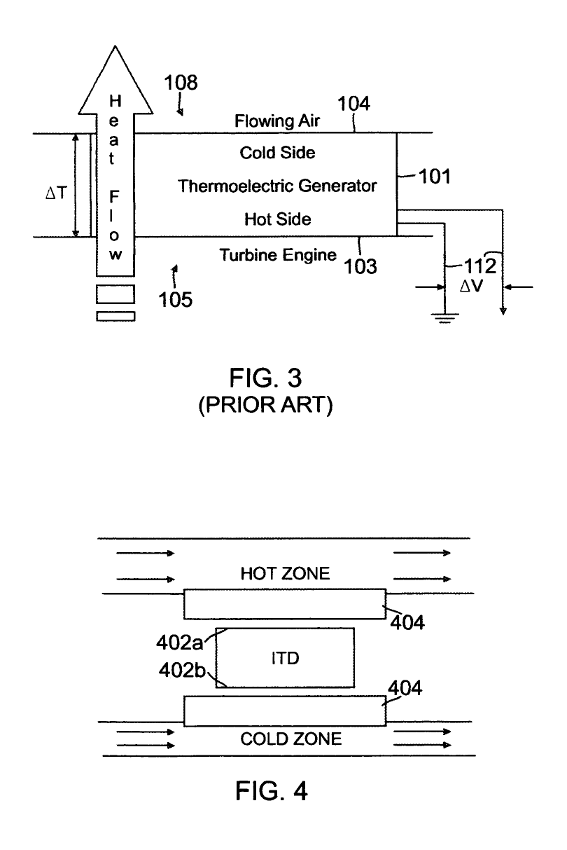

### DETAILED DESCRIPTION OF THE DISCLOSURE

Embodiments of the present disclosure now will be described more fully hereinafter with reference to the accompanying drawings. However, many different embodiments are contemplated and the present disclosure should not be construed as limited to the embodiments set forth herein; rather, these embodiments are provided so that this disclosure will be thorough and complete and better convey the scope of the disclosure to those skilled in the art.

In its broadest sense, this disclosure presents an improved thermoelectric device having the ability to increase the efficiency of conventional thermoelectric converters. The disclosure also encompasses an engine configuration including an improved thermoelectric assembly, comprising an array of such devices, disposed in a strategically located environment in the engine between hot and cold sources of temperature.

FIG. 4 shows the improved thermoelectric device ITD according to the present disclosure. In general, each, or both, of the upper and lower surfaces 402a and 402b, respectively, of the improved thermoelectric device ITD support a substantially planar, surface extender, element 404 attached to or disposed in close proximity thereto. The surface extender elements can be configured as fins, overlying plates, or a layer of porous media, made from any materials with properties such as high thermal conductivity fluid compatibility, high temperature survivability, low coefficient of thermal expansion, high specific surface area, low density. Materials that would provide such properties include, but are not limited to, metals (e.g. copper, aluminum, tin, nickel, silver, gold), ceramics (e.g. boron nitride, silicon nitride, silicon carbide, silicon nitride, hafnium carbide, tantalum carbide), and carbon (e.g. graphitized carbon).

The surface extender elements are mounted to the upper and lower surfaces of the improved thermoelectric device in such a manner as to be positioned adjacent a hot zone H and a cold zone C, effectively to spread and intensify the heat transfer in the respective zone over the corresponding surface of the thermoelectric device. The fluid flow in the hot and cold zones can be in the same direction or in opposite directions, and the flows can be parallel or perpendicular to the upper and lower surfaces of the improved thermoelectric device. The surface extender elements can be directly or indirectly coupled to the improved thermoelectric device ITD. A porous surface extender element 404 must be arranged vis-s-vis the thermoelectric device so that part or all of the fluid stream flows therethrough. The gas streams (flows) can be in arbitrary orientations relative to the TE device. There can also be a single TE device or an arbitrary number of TE devices (e.g. in an array). The TE device may be installed on either the “hot side” or the “cold side”, or it may be sandwiched in the middle. The porous material depicted on the hot and cold sides does not need to be of the same material or dimensions.

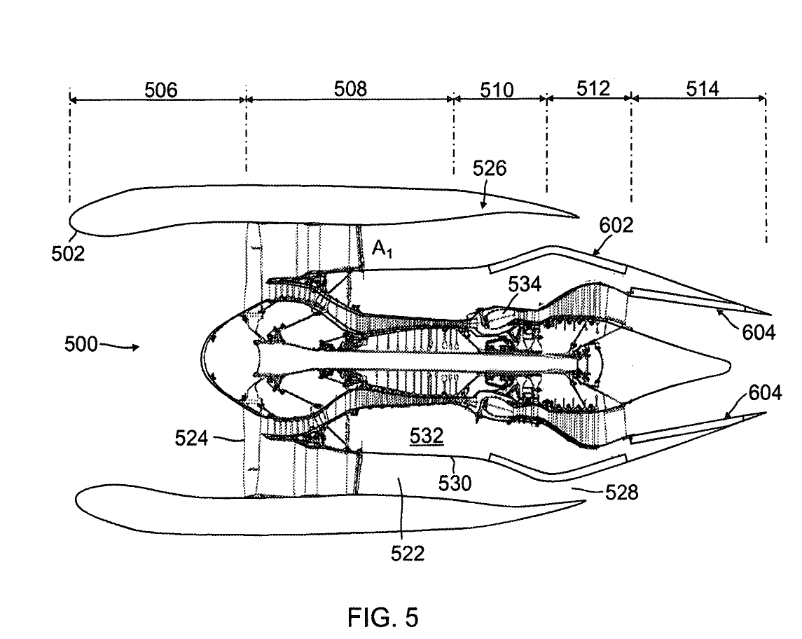

FIG. 5 generally shows a turbine engine 500 housed in an engine nacelle 502 mounted to an aircraft support structure. The engine includes an inlet section 506, a compressor section 508, a combustion section 510, a turbine section 512, and a nozzle section 514. A fan duct 522 extends between an inlet fan 524 in the fan cowl 526 and a fan exhaust nozzle 528 defined between the downstream end of the nacelle 502 and the exterior surface 530 of the engine core casing 532, which has its greatest diameter in the vicinity of the downstream end of the nacelle. The inner surface of the engine core casing constrains, with the engine core at the nozzle section of the engine, the downstream flow of the combusted gases

The turbine engine 500 achieves efficiency by driving a portion A₁ of the incoming airflow through the fan duct 522 using the inlet fan 524 located. The remainder of the incoming airflow moves downstream through the compressor section 508 where it is compressed, and then to the combustion section where it is burned in a combustion chamber 534. A set of high and low pressure turbines located in the turbine section 512 is used to convert the fluid energy in the engine airflow to mechanical energy. Thereafter, the “cool” fan airflow and the “hot” combustion gases are exhausted from the engine. In the case of military-type engines, where mixer nozzles are used, both cooler fan airflow and hot core exhaust airflow are brought together in the nozzle section and exhausted from the turbine. In the case of most commercial-type engines, the airflows remain separated when exhausted, and this results in less weight and drag.

In an engine configuration such as is depicted in FIG. 5, optimum locations for the improved thermoelectric devices of the present disclosure have been determined to be those locations where the temperature differentials would be greatest. One location is shown generally at 602 in the turbine section of the engine at the exterior surface of the inner surface of the fan duct. A second location is shown generally at 604 in the nozzle section of the engine on an inner surface of a downstream portion thereof The devices can be used as single units, or they can be fashioned as an array of units with one or both surfaces that are exposed to the heated or cooled environment bearing extended surfaces.

At such turbine section and nozzle section locations, the thermoelectric converter devices are exposed to both hot and cold environments in close proximity to one another. That is, one surface of the improved thermoelectric device ITD would be exposed to a comparatively hot environment, e.g., hot gases of the turbine engine, and another surface of the improved thermoelectric device ITD would be exposed to a comparatively cold environment, e.g., airflow. Such locations fulfill the requirements for electrical power generation, while being protected from the undesirably high pressures and undesirably high velocity airflows normally found in turbine engines. Several types of turbine engines are commonly used: turbofan engines, turbojet engines, turboprop engines, and turboshaft turbine engines. Such turbine engines can be used to power aircraft, watercraft, and land vehicles. They can also be used for power generation and other purposes. The improved thermoelectric devices ITD can be configured to provide all of the electric power for an aircraft and/or to provide additional electric power for the aircraft. Thermoelectric devices of the kind disclosed herein can be added to an aircraft without having to resort to expensive redesign of the turbine engine, or without having to alter the proven aerodynamic design of an aircraft. As those skilled in the art will appreciate, altering the aerodynamic design of an aircraft can potentially adversely affect the aircraft's aerodynamic performance. Altering the aerodynamic design of an aircraft can also necessitate costly flight testing.

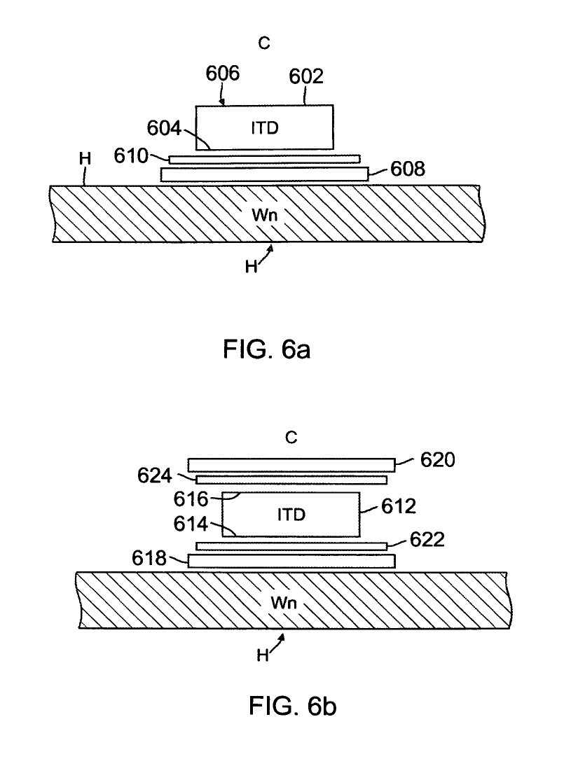

FIGS. 6a and 6b show two exemplary configurations of the improved thermoelectric device ITD contemplated by the present disclosure. It is to be understood that the possible configurations of the improved thermoelectric device ITD are not limited to those shown here, and that other configurations and arrangements of the improved thermoelectric device and extended surface elements will become apparent to those ordinarily skilled in the art.

FIG. 6a depicts a first version of the improved thermoelectric device 602 which is seen to have one surface 604 located in close proximity to an interior or an exterior wall W of a turbine. The wall W can constitute a “hot zone” H, and an opposing side 606 of the thermoelectric device can be exposed to a “cold zone” C (i.e., a temperature zone in which the temperature is colder than the temperature in the “hot” zone H), such as fan-driven ambient air or a liquid coolant. The thermoelectric device can have an extended surface element 608 mounted thereto. An additional interface element 610 can be interposed between the thermoelectric device 602 and the extended surface element 608.

FIG. 6b depicts a second version of an improved thermoelectric device 612 mounted in close proximity to an interior or an exterior wall W of a turbine. The wall W constitutes or is exposed to a “hot zone” H, and an opposing side 616 of the thermoelectric device is exposed to a “cold zone” C, such as fan-driven ambient air. The thermoelectric device has an extended surface element 618 mounted to one side 614 and a second extended surface element 620 mounted to the opposing side 616. An additional interface element 622 can be interposed between the improved thermoelectric device 612 and the extended surface element 618. A second interface element 624 can optionally be interposed between the thermoelectric device 612 and the extended surface element 620.

The materials used for the interface elements can be thermally conductive substances, such as metals (both conductive and semi-conductive), ceramics, and carbon. The interface elements have many uses, including isolating the thermoelectric devices from working fluids to prevent corrosion, facilitating manufacturing processes such as in promoting bonding or forming components, providing stress relief such as preventing large mismatches in thermal expansion coefficients between materials, etc.

Although the present disclosure has described the use of an improved thermoelectric apparatus in connection with aircraft engines where “hot” (e.g., engine exhaust) and “cold” (e.g., by-pass or ambient air, water, oil, glycol, or other coolant fluids) fields of thermally conductive materials are present or can be generated, it has utility in any technical field where distinct hot and cold environments are present. For example, if employed in an automotive or locomotive application, the cold environment could be external airflow or a liquid coolant. In an industrial or power plant application, the cold environment could be a liquid coolant.

While the disclosure has been made with reference to a preferred embodiment, it will be understood by those skilled in the art that various changes may be made and equivalents may be substituted for elements thereof without departing from the scope of this disclosure.

What we claim is:

1. An improved thermoelectric module, comprising:
a thermoelectric device having surfaces arranged for contact with comparatively hot and cold environments, and
an extended surface mounted in close proximity to at least one of the surfaces of said thermoelectric device, said extended surface comprising a layer of porous material having at least a portion immersed in at least one of said hot or cold environments.

2. The improved thermoelectric component of claim 1, wherein the comparatively hot and cold environments are in an engine and both of said surfaces include a layer of porous material proximate thereto, and further wherein at least a portion of both of said layers of porous material are disposed in the hot and cold environments, respectively.

3. The improved thermoelectric component of claim 1, wherein said porous material is thermally conductive and comprises one of a metal, a ceramic, and a graphitized carbon.

4. The improved thermoelectric component of claim 3, wherein said ceramic is chosen from the group of boron nitride, silicon nitride, silicon carbide, hafnium carbide, and tantalum carbide.

5. The improved thermoelectric component of claim 1, wherein said porous material has a low coefficient of thermal expansion and comprises one of a metal, a ceramic, and a graphitized carbon.

6. The improved thermoelectric component of claim 4, wherein said porous material is thermally conductive and the metal is chosen from the group of copper, aluminum, tin, nickel, silver, and gold.

7. The improved thermoelectric component of claim 1, wherein said porous material is ductile and will transfer heat quickly from one of the hot or cold environments to increase convective heat transfer to the thermoelectric component.

8. The thermoelectric component of claim 1, and further including an array of said thermoelectric devices sandwiched between opposing face sheets, wherein said extended surface is mounted adjacent to, and in close proximity with, one of the major surfaces of the opposing face sheets.

9. The thermoelectric component of claim 2, wherein the engine is an aircraft engine having a nacelle, and the thermoelectric device is mounted to a surface within the nacelle such that one porous layer is in contact with a fluid within the engine nacelle.

10. A method for thermal integration of a thermoelectric device, comprising:
providing an array of thermoelectric devices,
placing a first face sheet in close proximity to, and covering, one side of the array of thermoelectric devices,
placing a second face sheet in close proximity to, and covering, an opposing side of the array of thermoelectric devices,
providing a first layer of porous material in close proximity to the first face sheet to thereby form an improved thermoelectric component, and
positioning said first face sheet adjacent to a heated environment.

11. The method for thermal integration of a thermoelectric device as recited in claim 10, wherein the heated environment is in an aircraft engine, and further including
providing a second layer of porous material in close proximity to the second face sheet, and
positioning said second face sheet adjacent to a cooled environment.

12. A thermoelectric generation system, comprising:
an engine; and
at least one thermoelectric device disposed proximate the engine, said thermoelectric device including a porous layer on a surface thereof in proximity to said engine.

13. The thermoelectric generation system of claim 12, wherein the thermoelectric device is disposed proximate a heat source of the engine and a cooling source of the environment.

14. The thermoelectric generation system as recited in claim 12, wherein the thermoelectric device has two opposing surfaces bearing said porous layer, one surface being disposed proximate to the engine and the other surface being disposed proximate to an air flow.

15. The thermoelectric generation system of claim 12, wherein said engine comprises a turbine engine, and the thermoelectric device is mounted to the engine proximate to the exhaust nozzle.

16. The thermoelectric generation system of claim 12, wherein said engine comprises a turbine engine, and further including an array of thermoelectric devices sandwiched between opposing face sheets to form a module, said module being mounted to the engine proximate to the combustion section.

17. The thermoelectric generation system of claim 16, wherein at least one of said face sheets supports said porous material.

18. A method for generating thermoelectric energy, comprising:
mounting at least one thermoelectric device proximate an engine, said thermoelectric device including a porous layer on at least one surface thereof in proximity to said engine,
wherein the thermoelectric device is disposed proximate a heat source of the engine and a cooling source.

19. The method of claim 18, wherein the thermoelectric device has two opposing surfaces bearing said porous layer, one surface being disposed proximate to the engine and the other surface being disposed proximate to an air flow

20. The method of claim 18, wherein said engine comprises a turbine engine, and the thermoelectric device is mounted to the engine proximate to the exhaust nozzle.

21. The method of claim 18, wherein said engine comprises a turbine engine, and further including an array of thermoelectric devices sandwiched between opposing face sheets to form a module, said module being mounted to the engine proximate to the combustion section.
